(19) United States
(12) Patent Application Publication
(10) Pub. No.: US 2007/0222371 A1
(43) Pub. Date: Sep. 27, 2007

(54) Top-emitting OLED device with improved stability

(75) Inventors: Pranab K. Raychaudhuri, Rochester, NY (US); Joseph K. Madathil, Rochester, NY (US); Joel D. Shore, Rochester, NY (US)

Correspondence Address: Pamela R. Crocker;Patent Legal Staff, Eastman Kodak Company, 343 State Street, Rochester, NY, 14650-2201, US

(73) Assignee: Eastman Kodak Company

(21) Appl. No.: 11/385,274

(22) Filed: Mar. 21, 2006

(51) Int. Cl. H01J 1/62; H01J 63/04

(52) U.S. Cl. 313/504

(57) ABSTRACT

A top-emitting OLED device including a substrate; a reflective and conductive first electrode including a metal or metal alloy or both formed over the substrate; at least one organic layer formed over the first electrode and including an emissive layer having electroluminescent material; and a semitransparent, reflective and conductive second electrode provided over the organic layer, wherein the second electrode includes a first layer having material M, wherein M is a metal, and a second layer providing an anti-absorption function in contact with the first layer and having a compound M′X , wherein M′ is a ‘metal and X is a non-metal, wherein M′X has a free energy of formation [equal to or ]more negative than the free energy of formation of MX.

### FIELD OF THE INVENTION

The present invention relates to a top-emitting organic light-emitting diode device having metallic electrodes with improved reliability and enhanced operational stability.

### BACKGROUND OF THE INVENTION

An organic electroluminescent (OEL) device, alternately known as organic light emitting diode (OLED), is useful in flat-panel display applications. This light-emissive device is attractive because it can be designed to produce red, green, and blue colors with high luminance efficiency; operable with a low driving voltage on the order of a few volts, and clearly viewable from oblique angles. These unique attributes are derived from a basic OLED structure including a multilayer stack of thin films of small-molecule organic materials sandwiched between an anode and a cathode. Tang et al in commonly-assigned U.S. Pat. Nos. 4,769,292 and 4,885,211 disclose such a structure. The common electroluminescent (EL) medium includes a bilayer structure of a hole-transport (HTL) layer and an electron-transport layer (ETL), typically on the order of a few tens of nanometer (nm) thick for each layer. When an electrical potential difference is applied at the electrodes, the injected carriers, hole at the anode and electron at the cathode, migrate towards each other through the EL medium and a fraction of them recombines in the emitting layer (EML) a region close to the HTL/ETL interface, to emit light. The intensity of electroluminescence is dependent on the EL medium, drive voltage, and charge injecting nature of the electrodes. The light viewable outside of the device is further dependent on the design of the organic stack and optical properties of the substrate, and electrodes.

Conventional OLEDs are bottom emitting (BE), meaning that the display is viewed through the substrate that supports the OLED structure. The devices normally employ transparent glass substrates having a highly transparent indium-tin-oxide (ITO) layer that also serves as the anode. The cathode is typically a reflective thin film of Mg—Ag alloy, although lithium-containing alloys are also used as an efficient electron-injecting electrode. The light generated within the device is emitted in all directions. However, only a small fraction of generated light is available for viewing, and about 80% of generated light is trapped within the device in waveguiding modes in glass, ITO and organic layers. The light emitted toward the anode at less than the critical angle passes through the anode and through the substrate to the viewer, and the light emitted in the opposite direction is reflected at the cathode and passes through the anode and the substrate, enhancing the viewing intensity. A transparent substrate, a high-transparency anode and a high-reflectivity cathode are thus required to yield high luminance efficiency devices.

The OLED display elements are typically coupled with active matrix (AM) circuitry in order to produce high performance displays. The AM display uses switching elements of thin film transistors. The transistors are fabricated on glass substrates and are not transparent. Consequently the entire display area on the substrate is not available for the light to emerge. With the application of multi-transistor and complex circuitry in the backplane the open area through which the light emerges is significantly reduced. The ratio of the open area to that of the entire display area is called the aperture ratio. Due to the reduction of the aperture ratio the display will run dim. To compensate for the reduced average brightness level the drive current has to be increased subjecting the display to increased risk of operational degradation. It follows that further improvement in back plane design cannot be readily implemented without further compromising the aperture ratio and the operational stability.

To alleviate this problem the emitted light should emerge through the top surface. In the top-emitting design the drive circuitry is fabricated on substrate as in the bottom-emitting display but the light emerges through the surface opposite to the substrate. This design permits the use of complex circuitry occupying whatever substrate space is needed and the light-emitting area and the aperture ratio is not affected. The high aperture ratio makes the display viewable consuming less power. The devices have the prospect of running at low drive current while maintaining readability and thus extending the operational life.

In devices employing opaque backplanes such as silicon, the OLED must be of the top-emitting type. The top surface, usually the cathode, needs to be at least semitransparent to permit light to exit through the top. The device should preferably include a reflector or a reflecting anode opposite to the cathode side to redirect the light that strikes the anode to the cathode side.

Any device design should be aimed at achieving highest possible efficiency. However, realizing high efficiency by reclaiming light lost to waveguiding modes can be very difficult. To recover even a fraction of light lost to the waveguiding modes the device architecture can be very complex.

An approach to enhance the efficiency without introducing such complexity is to implement a microcavity design for the device, which includes reflecting electrodes. By employing highly reflective electrodes it is possible to remarkably increase the out-coupling of generated light. In microcavity OLEDs, metallic electrodes are generally preferred to meet the requirements of electrical conductivity and light transmission. To realize high efficiency a reflective opaque anode and a low absorption reflective cathode are needed. Sony Corporation (EP 1 154 676 A1) disclosed an anode made of light-reflecting materials such as Pt, Au, Cr, W, or presumably other high-work function materials in conjunction with an optional buffer/hole-injecting layer (HIL). Sony also disclosed (EP 1 102 317 A2) an anode composed of a transparent conducting film such as ITO formed on the reflecting layer. The top electrode is a semitransparent reflecting layer of MgAg or Al:Li alloy serving as the cathode through which the light emerges. Lu et al. disclose top-emitting, highly efficient OLEDs that use reflective metals in the anode structure, a phosphorescent emissive layer, Ir(ppy)₃, and a semitransparent compound cathode. (“High-efficiency top-emitting organic light-emitting devices”, M.-H. Lu, M. S. Weaver, T. X. Zhou, M. Rothman, R. C. Kwong, M. Hack, and J. J. Brown, Appl. Phys. Lett. 81, 3921 (2002)). Riel et al. (“Phosphorescent top-emitting organic light-emitting devices with improved light outcoupling”, H. Riel, S. Karg, T. Beierlein, B. Rushtaller, and W. Rieb, Appl. Phys. Lett. 82, 466 (2003) disclosed a high-efficiency top emitter, also using the Ir(ppy)₃ emissive layer, high work-function metal anodes, and semitransparent metal cathodes and further employing a ZnSe capping layer over the semitransparent compound cathode for improved light outcoupling. These top-emitters demonstrated efficiencies that are higher than the equivalent bottom-emitting non-microcavity devices. Raychaudhuri et.al. disclose top- and bottom-emitting microcavity devices that are twice as efficient as the optimized bottom-emitting non-microcavity device (“Performance enhancement of top- and bottom-emitting organic light-emitting devices using microcavity structures”, P. K. Raychaudhuri, J. K. Madathil, Joel D. Shore, and Steven A. Van Slyke, J SID Dec.3 (2004) p 315.

In top-emitting OLED the top electrode, the cathode usually includes a low work function metal or a metal on an electron-injecting surface. To achieve high efficiency the transparency of the top-electrode needs to be high requiring the use of a low absorption material in the thinnest possible form. Ag is most preferred as the top electrode as it meets the requirements very appropriately. Ag films can be made highly transmissive and reflective resulting in strong microcavity effect and significantly enhancing emission out-coupling. Furthermore, Ag thin film is sufficiently electrically conductive making implementation possible in a reasonably sized display without using an overlayer of a transparent conductive oxide (TCO) or buss lines.

One of the disadvantages of an Ag cathode is the unpredictability of device yield and irreproducibility of device characteristics. Some of the devices as made do not exhibit electroluminescence. The devices that initially work often fail in operation. The modes of failure include rapid performance degradation and catastrophic failure. In the rapid performance degradation mode the luminance falls and drive voltage rises very rapidly in operation. In the catastrophic mode the luminescence vanishes unpredictably and instantly. The devices showing no EL properties, as made or that fail in operation have or developed electrical shorts. The drive current flows through the shorting paths and not through the EL medium resulting in no electroluminescence.

The exact mechanism by which Ag induces shorting is not known. However, reactivity of Ag is high and its adhesion is low. The interface between the organic and Ag can be incomplete and unstable defects can exist. With the existence of these defects paths are generated in addition to normal carrier path resulting in a leaky or short-circuited diode. The leaky diodes are believed responsible for catastrophic failures in operation.

Another problem associated with thin electrode is that the film is not robust. In order to preserve the integrity of the electrode, a capping layer is often necessary. Furthermore, the capping layer when properly selected can also enhance the out coupling of light. The capping layer must be made of highly transparent materials. Deposition methods for transparent coating generally involve sputter deposition. Sputtering permits optimization during film deposition of the film composition needed for maximization of transparency. However, the sputtering deposition of the capping layer on the thin Ag layer increases the occurrence of short circuits between the anode and the cathodes causing further reduction of device yields. Thus, an alternative to Ag electrode is desired from the manufacturing point of view where consistency of process and high yield are of prime concern.

Aluminum, being highly reflective, electrically conductive and stable, is commonly used as a cathode in bottom emitting OLEDs. Al can also be one of the preferred top-electrode materials in a top-emitting device. However Al is not generally considered suitable because of expected low efficiency due to high absorptivity of Al. The absorbance of a 10 nm Al thin film is 30-50% in the visible wavelength range (“Optical Properties of Semi-transparent Metal Cathode for Top Emission Organic Light Emitting Diode”, Chan-Jae Lee, Dae-Gyu Moon, Jeong-In Han, Sung-Ho Baek, No-Hoon Park and Seoung-Sam Ju, Proceedings of the 8^{th} Asian Symposium on Information Display, p 693, Feb. 15-17, 2004, Nanjing, China). The absorbance of a Ag film of comparable thickness is 5-10%. Thin metallic films generally require a capping layer to preserve their integrity. A capping layer including high transparency materials is employed to limit to attenuation of the emitted light. When properly selected the capping layer can enhance the output of a top-emitting device. Mechanistically, the capping layer increases the luminance, primarily by reducing the absorption of light within the semi-transparent cathode (“Performance enhancement of top- and bottom-emitting organic light-emitting devices using microcavity structures”, P. K. Raychaudhuri, J. K. Madathil, Joel D. Shore, and Steven A. Van Slyke, J SID Dec.3 (2004) p 315). Thus the capping layer is also termed as the absorption reduction layer (ARL) or the antiabsorption layer (AAL). From an optical simulation study of a TE OLEDs with 10-nm Al cathode an increase of total emission amounting to 70% is predicted for a 60-nm thick ITO capping layer. (“Optical Simulation of Top-emitting Organic Light Emitting Diodes, H. J. Peng, C. F. Qie, Z. L. Xie, H. Y. Chen, M. Wong and H. S. Kwok, Proceedings of the 8^{th} Asian Symposium on Information Display, p 331, Feb. 15-17, 2004, Nanjing, China). For semitransparent Ag cathode an antiabsorption layer of Alq having similar optical properties as ITO typically increases the emission by only about 20%. It is possible that an antiabsorption layer is more effective on a metal layer with higher absorbance. Even with higher enhancement of top-emission with a capping layer the semitransparent Al electrode devices may still not be as efficient as the device that uses Ag as the semitransparent electrode. However, manufacturing yield and operational stability should be superior to those of the Ag electrode devices.

The electrode structure involving Al can be unstable if the capping layer is not properly selected. One of the most commonly used capping layers is ITO. Thermodynamic data suggest that the components of ITO, In₂O₃ and SnO₂, are reducible by Al. In operation the reduced In and Sn can accumulate at the electrode-capping layer interface degrading the device performance. In extended operation the In and Sn can diffuse through the cathode and eventually creating electrical shorts between the anode and the cathode causing complete failure of the device. As Al is very reactive to many oxides, nitrides and other compounds that included in the transparent capping layer, the electrode structure can be unstable. For long-term stability consideration, the capping materials should be selected on the basis of thermodynamic functions, particularly the free energy function. It should be recognized that the conductance of a thin semitransparent Al film is far superior to those of TCO films. Hence the capping layer is not restricted to a TCO allowing access to a wider variety of transparent materials.

### SUMMARY OF THE INVENTION

It is therefore an object of the present invention to provide a top-emitting OLED device (TE-OLED) with improved long-term operational stability. Another object of the present invention is to provide a device capable of being manufactured with high yield. It is a further object of this invention to provide a cathode with increased lateral electrical conductivity for improved a real uniformity of luminance.

These objects are achieved by an OLED device capable of emitting light through the top electrode of such device comprising:

(a) a substrate;

(b) a reflective and conductive first electrode including a metal or metal alloy or both formed over the substrate;

(c) at least one organic layer formed over the first electrode and including an emissive layer having electroluminescent material; and

(d) a semitransparent, reflective and conductive second electrode provided over the organic layer, wherein the second electrode includes a first layer having material M, wherein M is a metal, and a second layer providing an anti-absorption function in contact with the first layer and having a compound M′X , wherein M′ is a ′metal and X is a non-metal, wherein M′X has a free energy of formation equal to or more negative than the free energy of formation of the compound MX.

### BRIEF DESCRIPTION OF THE DRAWINGS

FIG. 1 shows schematically the layer structure of an OLED of the present invention;

FIG. 2 shows schematically the layer structure of an OLED according to another embodiment of the present invention; and

FIG. 3 shows schematically the layer structure of an OLED according to yet another embodiment of the present invention.

### DETAILED DESCRIPTION OF THE INVENTION

Throughout the ensuing description acronyms are used to designate the names of the different organic layers and operating features of organic light-emitting devices. For reference they are listed in Table 1.

TABLE 1

| | |
|---|---|
| OLED | Organic light-emitting diode |
| ITO | Indium tin oxide |
| IZO | Indium zinc oxide |
| HIL | Hole- injection Layer |
| HTL | Hole-transport layer |
| EML | Emissive layer |
| ETL | Electron-transport layer |
| EIL | Electron injection layer |
| AAL | Anti-absorption layer |
| ARL | Absorption reduction layer |
| NPB | 4,4′-Bis[N-(1-naphthyl)-N-phenylamino]biphenyl (NPB) |
| Alq | Tris(8-hydroxyquinoline) aluminum |
| TCO | Transparent conductive oxide |

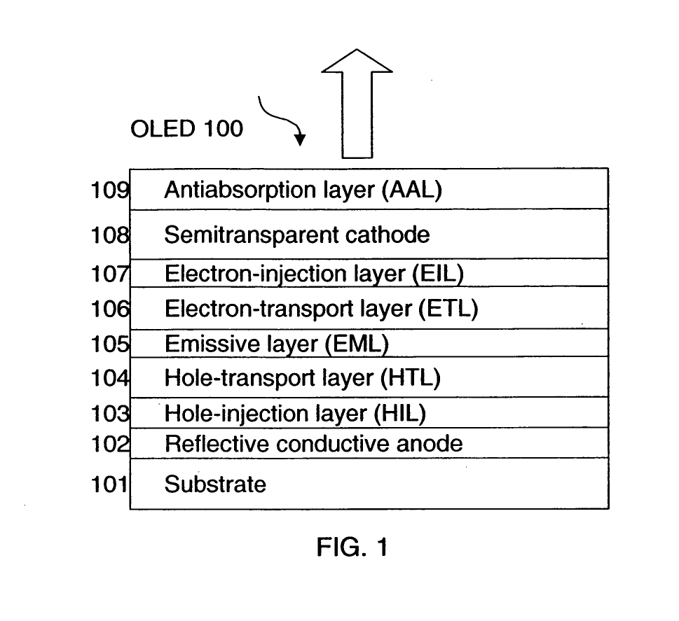

Turning to FIG. 1, the OLED 100 is a top-emitting OLED device of the present invention, which includes a reflective and conductive anode 102, a hole-injection layer (HIL) 103, a hole-transport layer (HTL) 104, an emissive layer (EML) 105, an electron-transport layer (ETL) 106, an electron-injection layer (EIL) 107, a semitransparent cathode 108, and an anti-absorption layer (AAL) 109 successively disposed over a substrate 101. In this embodiment the reflective and conductive anode 102 is the first electrode, and the second electrode includes the semitransparent cathode 108 as the first layer and the AAL layer 109 as the second layer. The semitransparent cathode 108 provides the function of injecting electrons, and the AAL layer 109 provides the antiabsorption function.

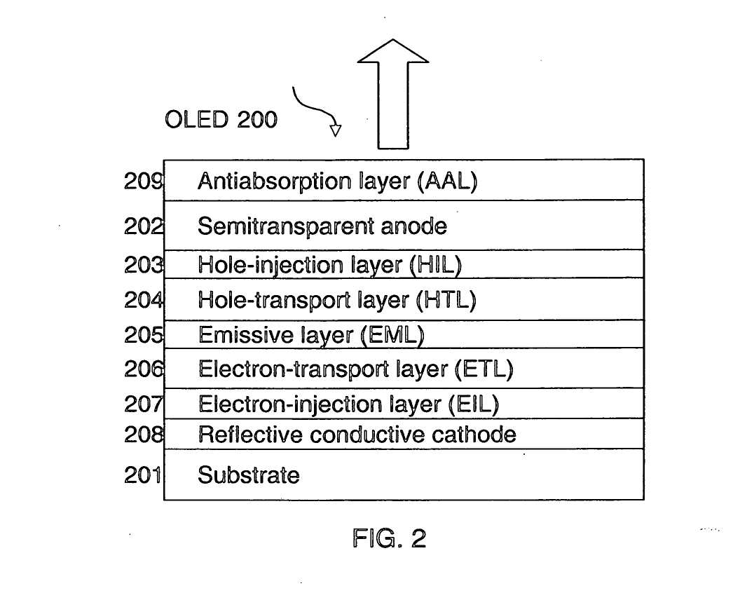

According to another embodiment of the present invention as shown in FIG. 2, the OLED 200 includes a reflective and conductive cathode 208, an electron-injection layer (EIL) 207, an electron-transport layer (ETL) 206, an emissive layer (EML) 205, a hole-transport layer (HTL) 204, a hole injection layer (HIL) 203, a semitransparent anode 202, and an anti-absorption layer (AAL) 209 successively disposed over a substrate 201. In this embodiment the reflective and conductive cathode 208 is the first electrode, and the second electrode includes the semitransparent anode 202 as the first layer and the AAL layer 209 as the second layer. The semitransparent anode 202 provides the function of injecting holes, and the AAL layer 209 provides the antiabsorption function.

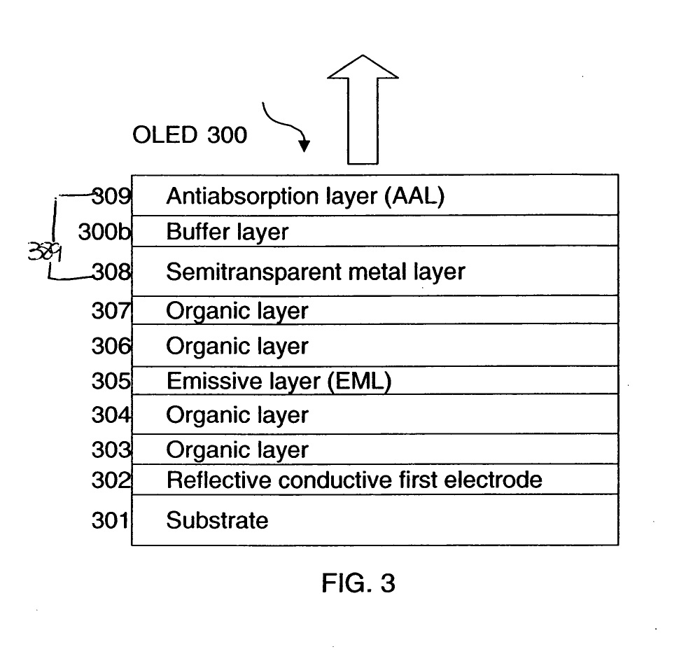

According to yet another embodiment of the present invention as shown in FIG. 3, the OLED 300 includes a reflective and conductive first electrode 302, a plurality of organic layers 303 through 307 including an emissive layer 305 and a semitransparent second electrode 389 successively deposited over a substrate 301. The second electrode 389 includes a semitransparent metal layer 308 as the first layer and an AAL layer 309 as the second layer and a buffer layer 300b inserted between the semitransparent metal layer 308 and the AAL layer 309. The semitransparent metal layer 308 provides the function of injecting a charge, and the AAL layer 309 provides the antiabsorption function. The buffer layer 300b can protect the organic layers 303-307 from damage if sputtering deposition is employed for the AAL layer 309.

In operation in the three embodiments, the first and the second electrode are connected to a voltage source and electrical current is passed through the organic layers, resulting in light generation in the emissive layer. The intensity of generated light is dependent on the luminescent and electrical characteristics of the organic layers as well as the charge-injecting natures of the electrodes and the charge-injection layers, and the magnitude of the electrical current passed through the OLED device. A part of the generated light is emitted through the top electrode in the direction shown by the arrow. The emission viewable from the top surface is further dependent on the reflectance of the bottom electrode, the layer structure of the OLED, the transmittance of the semitransparent top electrode and the antiabsorption properties of the AAL layer.

The composition and the function of the various layers constituting the OLED device are described as follows.

Substrates 101 (FIG. 1), 201 (FIG. 2) and 301 (FIG. 3) can include any substrate, opaque, semitransparent or transparent including glass, ceramic, metal, alloy, plastics or semiconductor as the light emits through the surface opposite to the substrate. The substrates may take the form of rigid plate, flexible sheet, or curved surfaces. Since the OLED device fabrication does not require a high-temperature process, any material that can withstand process temperatures on the order of 100° C. is useful as substrates. The substrates can support drive electronics, which includes active-matrix circuitry that contains electronic addressing and switching elements. Active-matrix substrates can contain high temperature polysilicon thin-film-transistors, low-temperature polysilicon thin-film-transistors or amorphous silicon thin film transistors. Those skilled in the art will appreciate that other circuit elements can be used to address and drive the pixels of an OLED device.

The bottom electrode (FIG. 1) is the first electrode and the anode 102, which provides the function of injecting holes into the organic layer when a positive potential relative to the semitransparent cathode 108 is applied. The anode materials most typically include high work function metals such as Au, Pd, Pt or the like and their alloys. The anode 102 also serves as the reflector. The anode 102 should be thick, preferably thicker than 40 nm to make them sufficiently reflective, substantially opaque and reasonably conductive. By opaque it is meant that the transmission of an anode film on glass is less than 10% and sufficiently reflective means that the reflectivity is at least 50% of that of the bulk material. Although high reflectivity anode is preferred, the anode 102 can include any of the following metals: Ag, Al, Mg, Zn, Rh, Ru, Ir, Au, Cu, Pd, Ni, Cr, Pt, Co, Te, Mo, Hf, Fe, Mn, Nb, Ge, Os, Ti, V or W, or alloys or mixtures thereof to have significant top emission. The anode 102 can be fabricated by any deposition methods including sputtering or evaporation and may also be compatible with the manufacturing process for the OLED 100. The anode 102 including these materials may or may not need an overlying hole-injection layer 103.

The bottom electrode (FIG. 2) serves as the cathode 208 that provides the function of injecting electron into the organic layer when a negative potential relative to the semitransparent anode 202 is applied. The cathode 208 materials most typically include a low-work function metals such as Al, Mg, Zn or the like and their alloys. The cathode 208 also serves as the reflector. The cathode 208 (FIG. 2) should be thick, preferably thicker than 40 nm to make them sufficiently reflective, substantially opaque and reasonably conductive. By opaque it is meant that the transmission of a cathode film on glass is less than 10% and sufficiently reflective means that the reflectivity is at least 50% of that of the bulk material. Although high reflectivity cathodes are preferred, the cathode 208 can also include any of the following metals: Ag, Rh, Ru, Ir, Au, Cu, Pd, Ni, Cr, Pt, Co, Te, Mo, Hf, Fe, Mn, Nb, Ge, Os, Ti, V or W, or alloys or mixtures thereof to have significant top emission. The cathode 208 can be fabricated by any of the deposition methods including sputtering or evaporation and may also be compatible with the manufacturing process for the OLED 200. The cathode 208 including these materials may or may not need an overlying electron-injection layer 207.

The bottom electrode 301 (FIG. 3) can serve either as the anode or as the cathode that provides the function of injecting charge into the organic layer when an appropriate potential relative to the semitransparent second electrode is applied. The materials most typically include a metal or a metal alloy or both preferably having high reflectivity. In order to be sufficiently reflective the thickness should be greater than 40 nm.

Hole-injection layer 103 (FIG. 1) or 203 (FIG. 2) provides the function of increasing the efficiency of the hole injection from the reflective anode 102 (FIG. 1) or from the semitransparent anode 202 (FIG. 2), respectively. It has been shown in commonly assigned U.S. Pat. No. 6,208,077 that a layer of plasma polymerized fluorinated carbon is useful as a hole injection layer. The hole-injection layer 103 results in OLEDs with reduced operating voltage, increased luminance efficiency and enhanced operational stability. The fluorinated carbon hole-injection layer 103 includes CFₓ, wherein x is less than or equal to 3 and greater than 0. The method of preparation and the characteristics of CFₓ have been disclosed in commonly assigned U.S. Pat. No. 6,208,077. Some oxide hole-injecting material was found to provide functions similar to those of the CFx. The oxide hole-injecting layers can include oxides of Mo, V or Ru. A layer of these materials each about 30 nm thick on 120 nm thick ITO anode layer on glass substrate has been found useful in bottom-emitting non-microcavity OLEDs as a hole injector to TPD hole-transport layer (“Metal oxides as a hole-injecting layer for an organic electroluminescent device”, S. Tokito, K. Noda and Y. Taga, J. Phys. D; Appl. Phys. 29, 2750 (1996)). An ITO layer on Ag reflector has been used to enhance hole injection from the anode that would not presumably allow efficient hole injection to the HTL directly from the Ag. (“High-efficiency top-emitting organic light-emitting devices”, M.-H. Lu, M. S. Weaver, T. X. Zhou, M. Rothman, R. C. Kwong, M. Hack, and J. J. Brown, Appl. Phys. Lett. 81, 3921 (2002)). Similarly to impart a function of promoting the hole injection an ITO layer on Al has been disclosed. (US 2005/0127824A1) A hole-injecting layer including CFx or an oxide has provided efficient hole injection from many metal anodes regardless of the work function. Even high work function metals that are believed efficient hole injectors were further benefited from the hole-injecting layer. (“Performance enhancement of top- and bottom-emitting organic light-emitting devices using microcavity structures”, P. K. Raychaudhuri, J. K. Madathil, Joel D. Shore, and Steven A. Van Slyke, J SID Dec. 3, 2004. In the cited reference the CFx HIL was prepared by decomposition of CHF₃ gas in RF plasma. The MoOₓ layer was prepared by vacuum evaporation of MoO₃ and the deposited film was non-stoichiometric having the composition represented by MoOₓwherein x is less than 3 but greater than 2. The HIL depending on the conductivity and transparency is usable up to several tens of nanometers. The hole injectors for the metallic anodes can include CFₓ, ITO, IZO, Pr₂O₃, TeO₂, CuPc, SiO₂, VOₓ, MoOₓ, or Ru₂O₃ or mixtures thereof. In order to maintain the reflectivity of the bottom electrode the HIL 103 (FIG. 1) should preferably be thin or highly transmissive or both. The HIL 203 (FIG. 2) should also be preferably thin or highly transmissive or both to permit the generated light to pass through the top surface of the device. The thickness of the HIL is limited to several tens of nanometers.

Hole-transport layer 104 (FIG. 1) or 204 (FIG. 2) provides the function of transporting holes to the emissive layer 105 or to the emissive layer 205. Hole-transport materials include various classes of aromatic amines as disclosed in commonly assigned U.S. Pat. No. 4,720,432. A preferred class of hole-transport materials includes the tetraaryldiamines of formula (I). 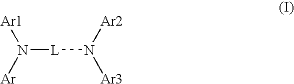
wherein:
Ar, Ar1, Ar2 and Ar3 are independently selected from among phenyl, biphenyl and naphthyl moieties;
L is a divalent naphthylene moiety or dₙ;
d is a phenylene moiety;
n is an integer of from 1 to 4; and
at least one of Ar, Ar1, Ar2 and Ar3 is a naphthyl moiety.

Useful selected (fused aromatic ring containing) aromatic tertiary amines are the following:
4,4′-Bis[N-(1-naphthyl)-N-phenylamino]biphenyl (NPB)
4,4″-Bis[N-(1-naphthyl)-N-phenylamino]-p-terphenyl
4,4′-Bis[N-(2-naphthyl)-N-phenylamino]biphenyl
1,5-Bis[N-(1-naphthyl)-N-phenylamino]naphthalene
4,4′-Bis[N-(2-pyrenyl)-N-phenylamino)]bi-phenyl
4,4′-Bis[N-(2-perylenyl)-N-phenylamino]biphenyl
2,6-Bis(di-p-tolylamino)naphthalene
2,6-Bis[di-(1-naphtyl)amino]naphthalene

Thickness of the HTL is chosen to maximize the luminance and its selection is dependent on the optical stack including the device. Both electrodes of the device of the present invention are metallic and substantially reflective; the optical path lengths from the emissive zone to the electrodes are to be chosen following a microcavity model in reference to FIG. 1, FIG. 2 or FIG. 3.

Emissive layer 105 (FIG. 1) or 205 (FIG. 2) or 305 (FIG. 3) provides the function of light emission produced as a result of recombination of holes and electrons in this layer. A preferred embodiment of the emissive layer includes a host material doped with one or more fluorescent dyes. Using this host-dopant composition, highly efficient OLED devices can be constructed. Simultaneously, the color of the EL devices can be tuned by using fluorescent dyes of different emission wavelengths in a common host material. Tang et al. in commonly assigned U.S. Pat. No. 4,769,292 has described this dopant scheme in considerable detail for OLED devices using Alq as the host material. As set forth in the Tang et al. commonly assigned U.S. Pat. No. 4,769,292, the emissive layer can contain a green light-emitting doped material, a blue light-emitting doped material, or a red light-emitting doped material.

Preferred host materials include the class of 8-quinolinol metal chelate compounds with the chelating metals being Al, Mg, Li, Zn, for example. Another preferred class of host materials includes anthracene derivatives such as 9,10 dinaphthyl anthracene; 9,10 dianthryl anthracene; and alkyl substituted 9,10 dinaphthyl anthracene, as disclosed in Shi et al. commonly assigned U.S. Pat. No. 5,935,721.

Dopant materials include most fluorescent and phorphorescent dyes and pigments. Preferred dopant materials include coumarins such as coumarin 6, dicyanomethylenepyrans such as 4-dicyanomethylene-4H pyrans, as disclosed in Tang et al. commonly assigned U.S. Pat. No. 4,769,292 and in Chen et al. in commonly assigned U.S. Pat. No. 6,020,078.

Electron-transport layer 106 (FIG. 1) or 206 (FIG. 2) provides the function of delivering electrons injected from the cathode to emissive layer. Useful materials include Alq, benzazoles, as disclosed in commonly assigned Shi et al. commonly assigned U.S. Pat. No. 5,645,948.

Electron-injection layer 107 (FIG. 1) or 207 (FIG. 2) provides the function of increasing the efficiency of the electron injection from the semitransparent cathode 108 (FIG. 1) or from the reflective cathode 208 (FIG. 2), respectively. The electron injection layer includes low work function metals including alkali metals, alkaline earth metals, rare earth metals or compounds thereof. In order for the generated light to pass through the semitransparent electrode, the EIL107 in FIG. 1 should preferably be thin or highly transmissive or both. For the device of FIG. 2 the EIL 207 should also be preferably thin or highly transmissive or both to insignificantly affect the reflectivity of the cathode 208. High reflectance of the bottom electrode is desired for high efficiency devices. The thickness of the EIL is limited to several tens of nanometers.

The second electrode is semitransparent, reflective and conductive and includes a semitransparent metal layer as the first layer (layer 108 (FIG. 1), or layer 202 (FIG. 2), or layer 308 (FIG. 3). The first layer acting either as a cathode or as an anode, injects an appropriate charge in to the organics. When the first layer acts as a cathode it includes a metal or metal alloy of work function of 4.0 eV or lower. The first layer can also include a compound of an alkali or an alkaline earth metal, such as LiF CaF₂ or the like, and a reactive metal like Al, Mg etc.

When the first layer acts as an anode it can include a metal M, Al for example, with a hole injector which includes, but not limited to CFₓ, ITO, IZO, Pr₂O₃, TeO₂, CuPc, SiO₂, VO_{X}, MoOₓ, or Ru₂O₃. M can be any reflective metal such as Zn, Mg, Ca, Pd or Pt. The first layer being metallic is not fully transparent but sufficiently transmissive to permit the generated light to pass through the top surface. By transmissive it is meant that the transmittance of the film on glass is 20% or more in the visible wavelength range. The first layer should be greater than about 4 nm in thickness to be laterally conductive, but less than about 50 nm so as not to cause excessive absorption of the emitted light.

The second electrode also includes a layer (layer 109 (FIG. 1), or layer 209 (FIG. 2), or layer 309 (FIG. 3) as the second layer. The second layer should be as transmissive as possible in order for the generated light to emit through the top with minimum attenuation. The second layer when properly selected can increase the on-axis top emission. The enhancement is primarily due to reduction of absorption of light within the semitransparent metallic layer. Since the first layer is conductive the second layer having the antiabsorption function need not be laterally conductive The AAL can be conductive or nonconductive, inorganic or organic and include but not limited to metal oxides, metal nitrides, metal fluorides, metal carbides or mixtures thereof. The second layer can also help preserve the integrity of the thin top electrode.

The first layer generally includes reactive metals and the second layer is made up of metallic compounds. If not properly selected the two layers can chemically react causing degradation of device performance and its eventual failure. For example, Al can be used as the first layer and a widely used transparent conductive oxide (TCO) such as ITO can be used as the second layer. To determine the stability of the interface one can examine thermodynamic functions, particularly the free energy function of the reactants and the potential products of the reaction. The reactants are Al and the components of ITO which are In₂O₃ and SnO₂, and the potential products of reaction are Al₂O₃, In and Sn. The standard free energy of formation of Al₂O₃ at 0° K., ΔG (Al₂O₃), is −266.6 Kcal/mole O₂. The ΔG (In₂O₃) is −148.0 Kcal/mole O_{2,} and the ΔG (SnO₂) is −138.8 Kcal/mole O₂ and those of pure elements are 0 by definition. The standard free energy of formation of a compound is an indication of its stability, the more negative the value the more stable compound is. It follows that Al₂O₃ is more stable than In₂O₃ or SnO₂. Thus a reaction at the Al/ITO interface is likely; Al will be oxidized with the formation of Al₂O₃, and the In₂O₃ and SnO₂ will be reduced with formations of In and Sn, respectively. Similarly on the basis of free energy functions it is predicted that if IZO is selected as the AAL layer instead of ITO the Al/IZO interface will also be thermodynamically unstable. Therefore ITO and IZO are not selected according to the present invention. The ΔG (MgO)=−286 Kcal/mole O₂ which is more negative than ΔG (Al₂O₃). If MgO is selected as the second layer the interface with Al first layer is stable, as the Al will not reduce the MgO. Thus MgO is an appropriate AAL material according to the present invention. In accordance with the present invention Al₂O₃ is another appropriate AAL material. This is because Al₂O₃ in the second layer will not oxidize Al first layer, or Al in the first layer will not reduce Al₂O₃ second layer. Thus, in accordance with the invention, if the first layer includes a metal M and the second layer includes a compound M′X where M′ is a metal and X is non metal then in order for the M/M′X interface to be stable the free energy of formation of the compound M′X has to be more negative than or equal to the free energy of formation of MX. The nonmetal X can be oxygen or nitrogen or a halogen or carbon.) The AAL materials include oxides of Ac, Al, Ba, Be, Ca, Hf, Li, Mg, Sc, Sr, Th, Y, Zr or rare earth metals, halides of Ac, Al, Ba, Be, Ca, Hf, La, Li, K, Mg, Na, Sc, Sr, Th, Y, Zr or rare earth metals, nitrides of Al, Ce, Hf, Ti, or Zr, and carbides of Al, Si, Ti or Zr or mixtures thereof. The thickness of the AAL layer is selected to maximize the on-axis luminance. The thickness is dependent on the optical properties of the material and ranges from 20 nm to 150 nm.

The antiabsorption layer (AAL) 109 (FIG. 1) or 209 (FIG. 2) or 309 (FIG. 3) provides the function of increasing the top on-axis emission primarily by reducing the absorption of light within the semitransparent top electrode. An appropriate thickness of the AAL layer is needed to maximize the top-emission, and depending on the optical properties of the AAL material the appropriate thickness lies in the range of from 30 to 300 nm The AAL can also help preserve the integrity of the thin top electrode. The second layer is preferably deposited by evaporation to minimize damage to the organic layers. The deposition of evaporable organic AAL is readily done, as the deposition process can be compatible with that of the organic layers of the OLED. Inorganic compounds that are evaporable at temperature accessible to resistive heating can be deposited by thermal evaporation. Heating to high temperatures using electron beam can evaporate many low-vapor pressure metal oxides. Some oxides may partially decompose in high vacuum during evaporation and may require small amount of added oxygen in the environment to preserve the stoichiometry. Sputtering deposition is generally employed for oxides, nitrides, carbides and borides as the films can be deposited regardless of vapor pressure and that the sputtered film generally has the same composition as the source material. However, sputtering can be damaging to the ETL/EML within OLED devices. (“Ion-beam induced surface damages on tris-(8-hydroxyquinoline) aluminum”, L. S. Liao, L. S. Hung, W. C. Chan, X. M. Ding, T. K. Sham, I. Bello, C. S. Lee, and S. T. Lee, Appl. Phys. Lett. 75, 1619 (1999)). To minimize sputter-induced damage one can choose appropriate sputtering parameters, which may include low power. But, at low power the deposition can be unacceptably low, and a buffer layer (300b FIG in FIG. 3) can be inserted between the first layer (308 FIG. 3) and the second layer (309 FIG. 3) if high rate of deposition is desired. A thin transmissive layer including a material resistant to plasma can be used as a buffer layer to minimize damage to the organic layers during sputtering deposition. The buffer layers can include oxides of Mo or W or low absorption metals like Au, Cu, Ag or alloys thereof.

Most OLED devices are sensitive to moisture or oxygen or both, so they are commonly sealed in an inert atmosphere such as nitrogen or argon, along with a desiccant such as alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in U.S. Pat. No. 6,226,890. In addition, barrier layers such as Al₂O₃, SiOₓ, Teflon etc. and alternating inorganic/polymeric layers are known in the art for encapsulation.

OLED devices of this invention can employ various well-known optical effects in order to enhance their properties if desired. This includes optimizing layer thicknesses to yield maximum light transmission, using scattering layer to enhance light extraction, replacing reflective electrodes with light-absorbing electrodes to enhance contrast, providing anti-glare or anti-reflection coatings over the display, providing a polarizing medium over the display, or providing colored, neutral density, or color conversion filters over the display. Filters, polarizers, and anti-glare or anti-reflection coatings may be specifically provided over the cover or as part of the cover.

The invention has been described in detail with particular reference to certain preferred embodiments thereof, but it will be understood that variations and modifications can be effected within the spirit and scope of the invention.

### PARTS LIST

100 OLED device
102 anode
103 hole injection layer
104 hole-transport layer
105 emissive layer
106 electron transport layer
107 electron-injection layer
108 cathode
109 anti-absorption layer
101 substrate
200 OLED device
208 cathode
207 electron-injection layer
206 electron-transport layer
205 emissive layer
204 hole-transport layer
203 hole injection layer
202 transparent anode
209 anti-absorption layer
201 substrate
300 OLED device
302 first electrode
303 organic layer
304 organic layer
305 organic layer
306 organic layer
307 organic layer
305 emissive layer
389 second electrode
   Parts List cont'd
301 substrate
308 metal layer
309 anti-absorption layer
309b buffer layer

1. A top-emitting OLED device comprising:
(a) a substrate;
(b) a reflective and conductive first electrode including a metal or metal alloy or both formed over the substrate;
(c) at least one organic layer formed over the first electrode and including an emissive layer having electroluminescent material; and
(d) a semitransparent, reflective and conductive second electrode provided over the organic layer, wherein the second electrode includes a first layer having material M, wherein M is a metal, and a second layer providing an anti-absorption function in contact with the first layer and having a compound M′X, wherein M′ is a ‘metal and X is a non-metal, wherein M′X has a free energy of formation [equal to or ] more negative than the free energy of formation of MX.

2. The top-emitting OLED device of claim 1 wherein M is Al, Zn, Mg, Ca, Pd or Pt.

3. The top-emitting OLED device of claim 1 wherein X includes oxygen and M′ includes Al, Ba, Be, Ca, Hf, Li, Mg Sc, Sr, Y, Zr or rare earth metals.

4. The top-emitting OLED device of claim 1 wherein X includes a halogen and M′ includes Al, Ba, Be, Ca, Hf, K, Li, Mg Na, Sc, Y, Zr or rare earth metals.

5. The top-emitting OLED device of claim 1 wherein X includes nitrogen and M′ includes Al, B, Ce, Hf, Ti, Nb, Ti, or Zr.

6. The top-emitting OLED device of claim 1 wherein X includes a carbon and M′ includes Al, Si, Ti or Zr.

7. The top-emitting OLED device of claim 1 wherein the first electrode is anode and the second electrode is cathode.

8. The top-emitting OLED device of claim 1 wherein the first electrode is cathode and the second electrode is anode.

9. The top-emitting OLED device of claim 7 wherein the second electrode includes a metal or metal alloy of work function of 4.0 eV.

10. The top-emitting OLED device of claim 7 wherein the second electrode includes an alkali or an alkaline earth metal compound and a reactive metal.

11. The top-emitting device of claim 10 wherein the alkali metal compound is LiF.

12. The top-emitting device of claim 10 wherein the reactive metal is Al.

13. The top-emitting device of claim 1 wherein a buffer layer is laid over the second electrode.

14. The top-emitting device of claim 13 wherein the buffer layer includes oxides of Mo or W or mixtures thereof.

15. The top-emitting device of claim 13 wherein the buffer layer includes low absorption metals or metal alloys.

16. The top-emitting device of claim 13 wherein the low absorption metals include Ag, cu and Au or alloys thereof.

17. The top-emitting OLED device of claim 1 wherein the first electrode includes Ag, Al, Mg, Zn, Rh, Ru, Ir, Au, Cu, Pd, Ni, Cr, Pt, Co, Te, Mo, Hf, Fe, Mn, Nb, Ge, Os, Ti, V or W, or alloys or mixtures thereof.

18. The top-emitting OLED device of claim 1 wherein the thickness of the antiabsorption layer ranges from 40 nm to 300 nm.

19. The top-emitting OLED device of claim 1 further includes a hole- injection layer, a hole-transport layer, an electron-injection layer and an electron-transport layer.

20. The top-emitting OLED device of claim 19 wherein the hole injection layer includes CFₓ, ITO, IZO, Pr₂O₃, TeO₂, CuPC, SiO₂, VOₓ, MoOₓ, or Ru₂O₃ or mixtures thereof.

21. The top-emitting OLED device of claim 18 wherein the hole transport layer includes NPB.

22. The top-emitting OLED device of claim 18 wherein the electron transport layer includes Alq.

23. The top-emitting OLED device of claim 1 wherein the emissive layer includes Alq.

24. The top-emitting OLED device of claim 23 wherein the emissive layer contains fluorescent or phosphorescent dopants.

25. The top-emitting OLED device of claim 1 wherein the thickness of first electrode is in a range of from 50 nm to 200 nm.

26. The top-emitting OLED device of claim 1 wherein the thickness of the second layer is in a range of from 5 nm to 30 nm.
